(19) United States
(12) Patent Application Publication
(10) Pub. No.: US 2026/0326164 A1
(43) Pub. Date: Oct. 22, 2026

(54) MASK DRYING SYSTEM AND DRYING METHOD USING THE SAME

(71) Applicant: Samsung Display Co., Ltd., Yongin-Si (KR)

(72) Inventors: MYUNGKYU KIM, Yongin-si (KR); KYUNGHOON CHUNG, Yongin-si (KR); HYEONSIK KIM, Yongin-si (KR); YONG YEO, Yongin-si (KR); YONGSIC JEON, Yongin-si (KR)

(21) Appl. No.: 19/571,278

(22) Filed: Mar. 18, 2026

(30) Foreign Application Priority Data
Apr. 18, 2025 (KR) 10-2025-0050787

(51) Int. Cl. B08B 7/00; B08B 5/02; C23C 16/04; C23C 16/44

(52) U.S. Cl. CPC B08B 7/0071; B08B 5/02; C23C 16/4401; C23C 16/042

(57) ABSTRACT

The disclosure relate to a mask drying system capable of drying a residual cleaning solution efficiently, and the mask drying system includes an induction heating module configured to heat a mask which includes a mask frame and a mask sheet, and disposed on the induction heating module, a thermoelectric module disposed on an upper portion of the mask and a moving part disposed on the induction heating module and configured to move the induction heating module on a plane parallel to a surface of the mask frame.

### CROSS-REFERENCE TO RELATED APPLICATION(S)

This application claims priority under 35 U.S.C. § 119 to Korean Patent Application No. 10-2025-0050787, filed on Apr. 18, 2025, which is hereby incorporated by reference for all purposes as if fully set forth herein.

### BACKGROUND

### 1. Field

Embodiments relate to a mask drying system and a drying method using the same. More particularly, the embodiments relate to the mask drying system drying a residual cleaning solution on the mask and the drying method using the same.

### 2. Description of the Related Art

A display device may include signal lines formed on a substrate, transistors connected to the signal lines, and a light-emitting element that emits light in response to a current supplied through the transistors. A deposition mask such as a fine metal mask, an open mask, and the like may be used to form various patterns constituting the signal lines, the transistors, and the light-emitting element.

However, after the deposition process is completed, a cleaning process of the deposition mask using a cleaning solution and a drying process for drying the cleaning solution on the deposition mask are sequentially performed. In the drying process, a problem may be generated in which the residual cleaning solution is not completely removed between components of the deposition mask. Such a problem may cause deterioration in the lifetime of the deposition mask and in the quality of the display device manufactured using the deposition mask.

### SUMMARY

Embodiments provide a mask drying system with improved removal rate of residual cleaning solution.

The embodiments provide a mask drying method using the mask drying system.

A mask drying system according to an embodiment includes a mask including an induction heating module configured to heat a mask which includes a mask and a mask sheet, and disposed on the induction heating module, a thermoelectric module disposed on an upper portion of the mask and a moving part disposed on the induction heating module and configured to move the induction heating module on a plane parallel to a surface of the mask frame.

In an embodiment, the thermoelectric module may include a first thermoelectric module overlapping a first side of the mask frame in a plan view, the first side is located from the mask frame in a first direction and extends along a second direction crossing the first direction, a second thermoelectric module overlapping a second side of the mask frame, the second side is located from the mask frame in the second direction and extends along the first direction, a third thermoelectric module overlapping a third side of the mask frame, the third side is located from a direction opposite to the first direction, and extends along the second direction, and a fourth thermoelectric module overlapping a fourth side of the mask frame, the fourth side is located from a direction opposite to the second direction and extends along the first direction.

In an embodiment, the induction heating module may include a first induction heating module adjacent to the first side, and configured to heat the first side, a second induction heating module adjacent to the second side, and configured to heat the second side, a third induction heating module adjacent to the third side, and configured to heat the third side, and a fourth induction heating module adjacent to the fourth side, and configured to heat the fourth side.

In an embodiment, the mask drying system may further include a gas injecting module under the mask and configured to inject heated air toward a corner of the mask frame. The corner may be a region in which at least two of the first side, the second side, the third side, and the fourth side meet each other.

In an embodiment, the gas injecting module may include a first gas injecting module overlapping a corner of the mask frame in which the first side and the second side meet each other in a plan view, a second gas injecting module overlapping a corner of the mask frame in which the second side and the third side meet each other in a plan view, a third gas injecting module overlapping a corner of the mask frame in which the third side and the fourth side meet each other in a plan view, and a fourth gas injecting module overlapping a corner of the mask frame in which the first side and the fourth side meet each other in a plan view.

In an embodiment, the first gas injecting module may be located between the first induction heating module and the second induction heating module, in a plan view, the second gas injecting module may be located between the second induction heating module and the third induction heating module, in a plan view, the third gas injecting module may be located between the third induction heating module and the fourth induction heating module, in a plan view, and the fourth gas injecting module may be located between the first induction heating module and the fourth induction heating module, in a plan view.

In an embodiment, the first induction heating module, the second induction heating module, the third induction heating module, and the fourth induction heating module may be spaced apart from each other at the corner of the mask frame in a plan view.

In an embodiment, the first induction heating module, the second induction heating module, the third induction heating module, and the fourth induction heating module may be located below the mask.

In an embodiment, the first induction heating module, the second induction heating module, the third induction heating module, and the fourth induction heating module may partially overlap a frame opening of the mask frame.

In an embodiment, the first induction heating module, the second induction heating module, the third induction heating module, and the fourth induction heating module may be located above the mask.

In an embodiment, the first induction heating module, the second induction heating module, the third induction heating module, and the fourth induction heating module may surround the first thermoelectric module, the second thermoelectric module, the third thermoelectric module, and the fourth thermoelectric module, in a plan view.

In an embodiment, the moving part may include a first moving part coupled to the first induction heating module and the third induction heating module and configured to move the first induction heating module and the third induction heating module in a direction parallel to the first direction and a second moving part coupled to the second induction heating module and the fourth induction heating module and configured to move the second induction heating module and the fourth induction heating module in a direction parallel to the second direction.

A mask drying method according to an embodiment includes adjusting a location of an induction heating module corresponding to a location of a mask, heating the mask by switching a surface of a thermoelectric module facing the mask to a heating mode, injecting a heated air toward a corner in which at least two of sides of the mask meet each other, and switching the surface of the thermoelectric module to a cooling mode.

In an embodiment, the adjusting of the location of the induction heating module corresponding to the location of the mask may include moving the induction heating module so that the induction heating module overlaps the sides of the mask in a plan view and adjusting a distance between the mask and the induction heating module.

In an embodiment, the distance between the mask and the induction heating module may be from about 5 mm to about 15 mm.

In an embodiment, in the heating of the mask by switching the surface of the thermoelectric module facing the mask to the heating mode, a temperature of the surface of the thermoelectric module may be from about 60 °C to about 80 °C.

In an embodiment, the injecting of the heated air toward the corner, a temperature of the heated air is from about 60 °C to about 80 °C.

In an embodiment, the system may further include heating the sides of the mask by using the induction heating module.

In an embodiment, in the heating of the sides of the mask by using the induction heating module, a temperature of the induction heating module may be from about 60 °C to about 80 °C.

In an embodiment, in the switching of the surface of the thermoelectric module to the cooling mode, a temperature of the surface of the thermoelectric module may be about 15 °C or more.

In the mask drying system according to embodiments of the present disclosure, a residual cleaning solution on sides and corners of the mask may be dried or removed using a gas injecting module and an induction heating module. In addition, heat may be applied to an upper portion and a lower portion of the mask through the gas injecting module, the induction heating module, and a thermoelectric module to easily dry or remove the cleaning solution. Accordingly, the mask drying system capable of efficiently removing the cleaning solution may be provided.

In the mask drying method according to embodiments of the present disclosure, a mask drying process may be performed through switching of the thermoelectric module located above the mask from heating to cooling, and vice versa. Accordingly, efficiency of the drying process of the mask may be improved, and time and cost may be reduced.

### BRIEF DESCRIPTION OF THE DRAWINGS

Illustrative, non-limiting embodiments will be more clearly understood from the following detailed description in conjunction with the accompanying drawings.

FIG. 1 is a side view illustrating a mask drying system according to an embodiment of the present disclosure.

FIG. 2 is a view for explaining an example of operation of a thermoelectric module included in the mask drying apparatus of FIG. 1.

FIG. 3 is a view for explaining another example of operation of the thermoelectric module included in the mask drying apparatus of FIG. 1.

FIG. 4 is an exploded perspective view illustrating the mask of FIG. 1 in a disassembled state.

FIG. 5 is a plan view illustrating a portion of the mask drying system of FIG. 1.

FIG. 6 is a bottom view illustrating a portion of the mask drying system of FIG. 1.

FIG. 7 is a flowchart illustrating a drying method using the mask drying system of FIG. 1.

FIG. 8 is a view explaining a adjusting a location of the mask of FIG. 7.

FIG. 9 is a view explaining a adjusting a location of an induction heating module of FIG. 7.

FIG. 10 is a view explaining a switching a lower surface of the thermoelectric module contacting an upper portion of the mask of FIG. 7 to a heating mode.

FIG. 11 is a view explaining a injecting heated air toward a corner area of the mask of FIG. 7.

FIG. 12 is a view explaining a switching the lower surface of the thermoelectric module to a cooling mode.

FIG. 13 is a side view illustrating a mask drying system according to another embodiment of the present disclosure.

FIG. 14 is a block diagram illustrating an electronic device manufactured using the mask of FIG. 1.

FIG. 15 is schematic views illustrating various embodiments of the electronic device of FIG. 14.

FIG. 16 is a cross-sectional view illustrating a portion of a display module of FIG. 14.

### DETAILED DESCRIPTION OF THE EMBODIMENTS

Hereinafter, display devices in accordance with embodiments will be described in more detail with reference to the accompanying drawings. The same reference numerals are used for the same components in the drawings, and redundant descriptions of the same components will be omitted.

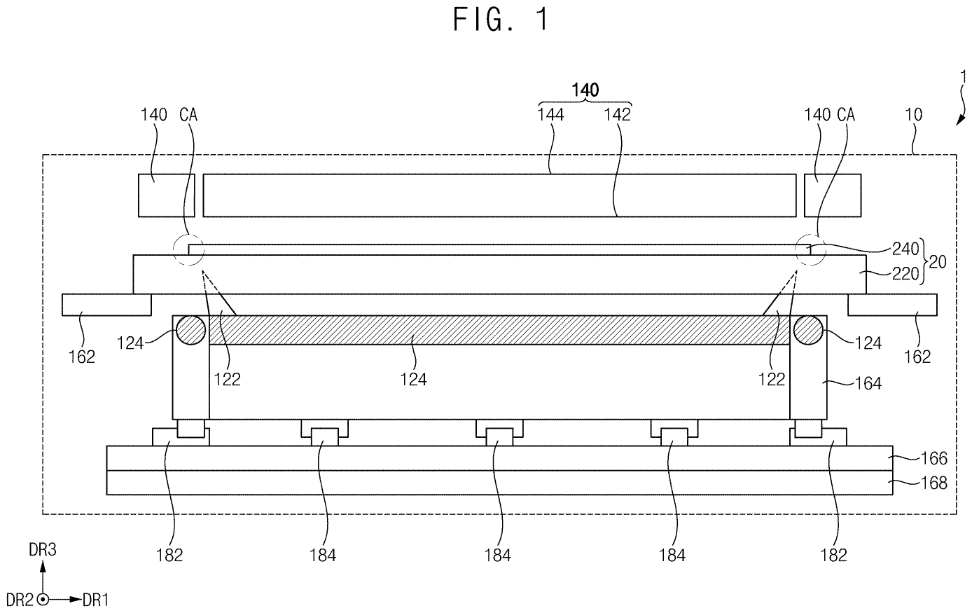

FIG. 1 is a side view illustrating a mask drying system according to an embodiment of the present disclosure.

Referring to FIG. 1, a mask drying system 1 according to an embodiment of the present disclosure may include a mask drying apparatus 10. A mask 20 which may be dried using the mask drying apparatus 10 is included in the drawings for ease of explanation. The mask drying apparatus 10 may include a gas injecting module 122, an induction heating module 124, a thermoelectric module 140, a stage 162, a first support 164, a first moving part 166, a second support 168, a second moving part 182, and a third moving part 184. The mask 20 may include a mask frame 220 and a mask sheet 240.

In the present disclosure, a plane may be defined by a first direction DR1 and a second direction DR2 crossing the first direction DR1. For example, the first direction DR1 and the second direction DR2 may be perpendicular to each other. In addition, a third direction DR3 may be perpendicular to the plane.

In an embodiment, the mask drying apparatus 10 may be a drying apparatus for drying a residual cleaning solution in the mask 20 after a cleaning process of the mask 20. In an embodiment, the mask drying system 1 may further include a process chamber (not shown) for performing a drying process. For example, the mask drying apparatus 10 and the mask 20 may be located in the process chamber.

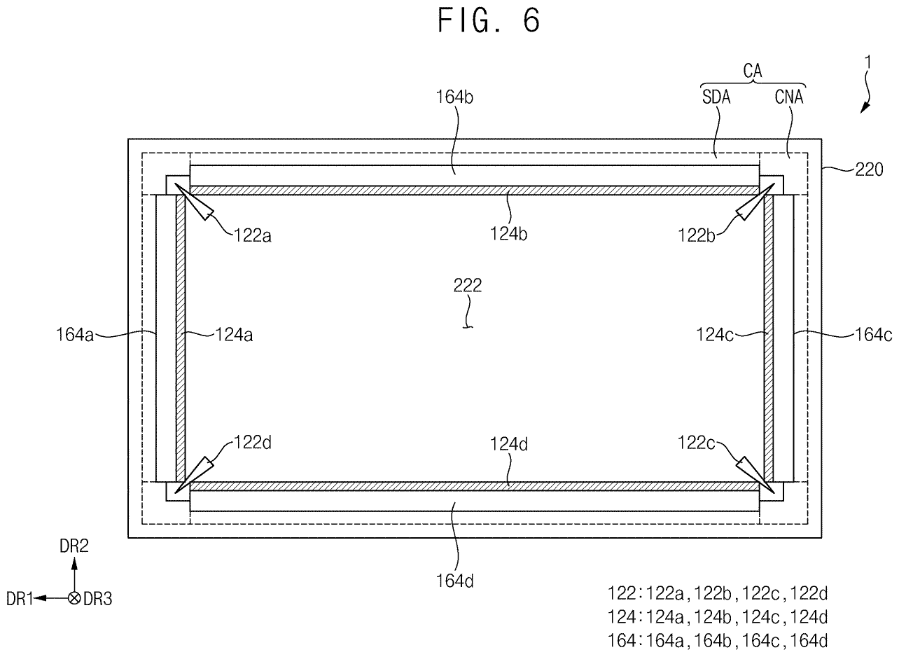

The gas injecting module 122 may spray heated air. For example, the gas injecting module 122 may have a nozzle for injecting the heated air. The nozzle of the gas injecting module 122 may be directed toward a contact area CA in which the mask frame 220 and an end of the mask sheet 240 contact each other. Specifically, the gas injecting module 122 may spray the heated air to four corner areas of the mask frame 220 (e.g., a corner area CNA of FIG. 6).

In an embodiment, the gas injecting module 122 may be located to correspond to locations of the four corners of the mask frame 220. For example, the gas injecting module 122 may include four modules disposed in areas corresponding to four corners of the mask frame 220.

In an embodiment, the gas injecting module 122 may be fixed to a component (e.g., the second support 168) located under the gas injecting module 122. In another embodiment, the gas injecting module 122 may be fixed to an inner surface of the process chamber. However, a fixing method of the gas injecting module 122 according to embodiments of the present disclosure may not be limited thereto, and the gas injecting module 122 may be fixed in various ways so as to spray air to the mask frame 220.

The induction heating module 124 may be located under the mask 20. The induction heating module 124 may be a module for drying by heating a portion of the mask 20. For example, the induction heating module 124 may heat the contact area CA of the mask frame 220. Specifically, the induction heating module 124 may apply heat to the contact area CA of the mask frame 220 to dry a residual cleaning solution between the mask frame 220 and the mask sheet 240 contacting with each other.

In an embodiment, the induction heating module 124 may heat the contact area CA of the mask frame 220 by directly supplying current or the like to the contact area CA, or may heat the contact area CA through radiant heat, convective heat, or the like from outside. In an embodiment, the induction heating module 124 may include a ring-shaped induction coil and may be a module for drying the mask 20 by an induction heating method. However, a drying method according to embodiments of the present disclosure may not be limited to the induction heating method, and a drying method using convective heat, radiant heat, or the like may also be used.

In an embodiment, the induction heating module 124 may be located to correspond to locations of the four sides of the mask frame 220. For example, the induction heating module 124 may include four modules overlapping the four sides of the mask frame 220.

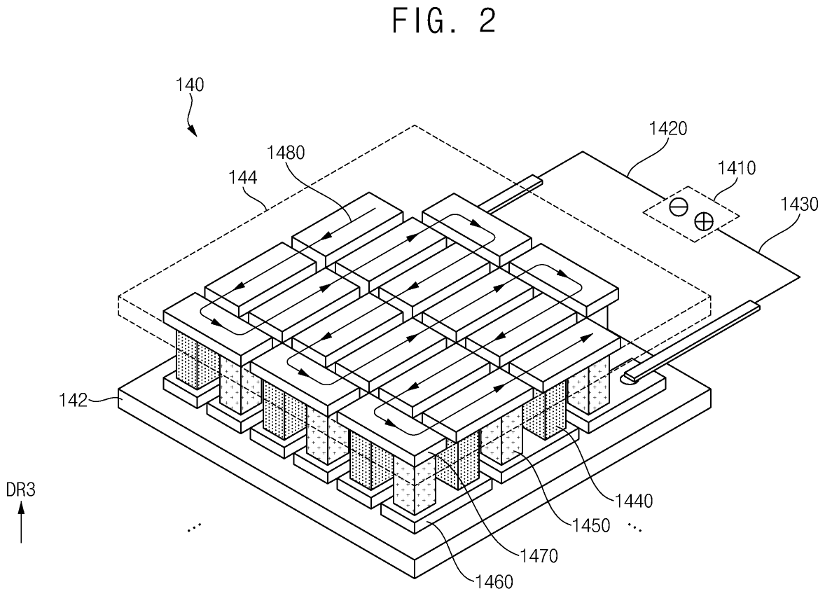

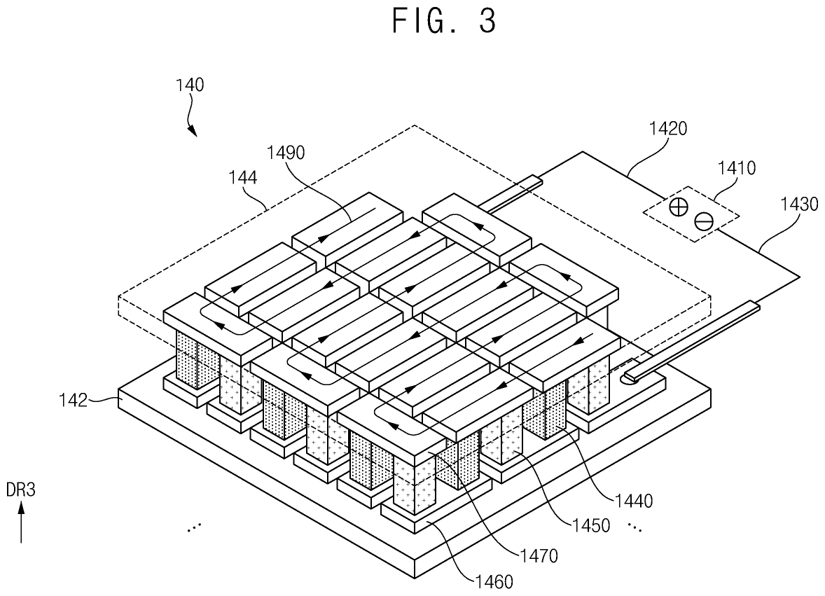

The thermoelectric module 140 may be located on an upper portion of the induction heating module in which the mask 20 is disposed. The thermoelectric module 140 may include a first plate 142 facing the mask 20 and a second plate 144 opposite to the first plate 142. In an embodiment, the thermoelectric module 140 may be a thermoelectric element or a Peltier element capable of performing heating and cooling functions at a same time. For example, when the first plate 142 is heated, the second plate 144 may be cooled. In addition, when the first plate 142 is cooled, the second plate 144 may be heated. Specifically, during a drying process of the mask 20, the first plate 142 facing the mask 20 may be heated, and after the drying process of the mask 20 is completed, the first plate 142 facing the mask 20 may be cooled. The structure of the thermoelectric module 140 will be described later with reference to FIGS. 2 and 3.

The stage 162 may support the mask 20 disposed thereon. For example, the mask frame 220 may be mounted on the stage 162. A fixing part for fixing the location of the stage 162 may be further located in the process chamber. The location of the stage 162 may be fixed or may be moved in the third direction DR3 through a separate moving part. The stage 162 may be located between the thermoelectric module 140 and the induction heating module 124.

The first support 164 may support the induction heating module 124. For example, the first support 164 may be coupled to the induction heating module 124 from under the induction heating module 124.

The first moving part 166 may move the induction heating module 124 and the first support 164 in a direction parallel to the third direction DR3. For example, a distance between the induction heating module 124 and the mask frame 220 may be adjusted through the first moving part 166. Accordingly, a drying speed of the residual cleaning solution in the mask 20 may be easily adjusted.

The second support 168 may be located under the first support 164. The second support 168 may form a base of the mask drying apparatus 10. The second support 168 may support a load of the first support 164. The second support 168 may be coupled to the first moving part 166. For example, when locations of the induction heating module 124 and the first support 164 are raised, the first moving part 166 may be raised in a direction away from the second support 168. When locations of the induction heating module 124 and the first support 164 are lowered, the first moving part 166 may be lowered in a direction toward the second support 168.

The second moving part 182 may move the induction heating module 124 in a direction parallel to the first direction DR1. Specifically, the second moving part 182 may move the induction heating module 124 extending along the second direction DR2 in a direction parallel to the first direction DR1. The second moving part 182 may be coupled to the first moving part 166 to simultaneously move the induction heating module 124 and the first support 164.

The third moving part 184 may move the induction heating module 124 in a direction parallel to the second direction DR2. Specifically, the third moving part 184 may move the induction heating module 124 extending along the first direction DR1 in a direction parallel to the second direction DR2. The third moving part 184 may be coupled to the first moving part 166 to simultaneously move the induction heating module 124 and the first support 164.

In an embodiment, the mask 20 may be a deposition mask. For example, the mask 20 may be a mask for depositing a deposition material, such as an organic material, on a substrate. The organic material may be a material (e.g., an organic light-emitting material) for forming a light-emitting layer that emits light. In an embodiment, the mask 20 may be a mask for manufacturing a display device or an electronic device including a micro light-emitting element. For example, the mask may be a fine metal mask (FMM). However, a type of the mask 20 according to embodiments of the present disclosure may not be limited thereto, and the mask 20 may be various types of masks used in semiconductor processes.

The mask frame 220 may be a structure for supporting the mask sheet 240. In an embodiment, the mask frame 220 may have a polygonal planar shape. In another embodiment, the mask frame 220 may have a circular or elliptical planar shape. In an embodiment, the mask frame 220 may include a silicon wafer. However, a shape of the mask frame 220 and a material included in the mask frame 220 according to embodiments of the present disclosure may not be limited thereto.

The mask sheet 240 may be located on the mask frame 220. The mask sheet 240 may partially contact the mask frame 220. For example, the mask sheet 240 may contact the mask frame 220 in a contact area CA. In an embodiment, in a plan view, a size of the mask sheet 240 may be less than a size of the mask frame 220.

In an embodiment, the mask sheet 240 may have a shape corresponding to the mask frame 220. For example, the mask sheet 240 may have a polygonal planar shape. In another example, the mask sheet 240 may have a circular or elliptical planar shape.

In an embodiment, the mask sheet 240 may include a conductive material, an inorganic material, or the like. For example, the conductive material may include titanium (Ti), titanium nitride (TiN), cobalt (Co), or nickel (Ni). These may be used alone or in combination with each other. For example, the inorganic material may include silicon (Si), silicon nitride (SiNₓ), silicon oxide (SiOₓ), or silicon oxynitride (SiOₓN_{y}). These may be used alone or in combination with each other. However, a shape of the mask sheet 240 and a material included in the mask sheet 240 according to embodiments of the present disclosure may not be limited thereto.

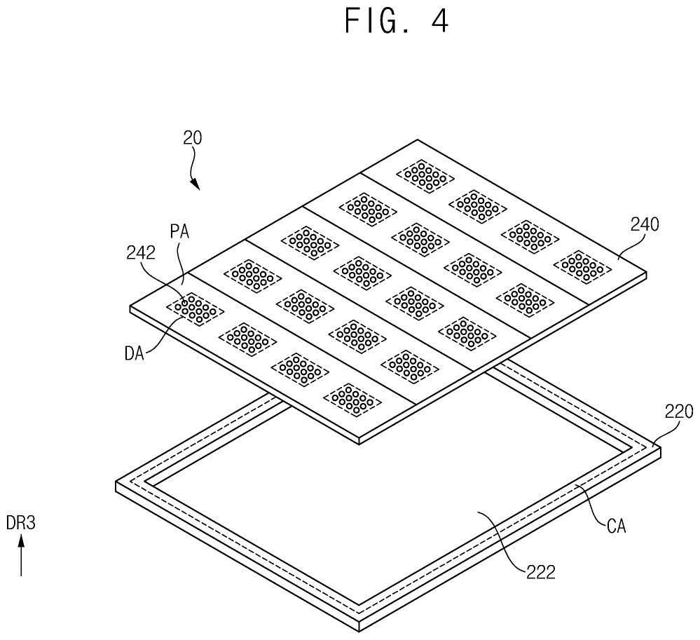

The mask frame 220 may have a frame opening (e.g., a frame opening 222 of FIG. 4) partially overlapping the mask sheet 240. The mask sheet 240 may have a deposition opening (e.g., a deposition opening 242 of FIG. 4) through which the organic material is transmitted. The contact area CA of the mask frame 220 may be adjacent to inner surfaces of the mask frame 220 that are boundaries of the frame opening 222.

FIG. 2 is a view for explaining an example of operation of a thermoelectric module included in the mask drying apparatus of FIG. 1. FIG. 3 is a view for explaining another example of operation of the thermoelectric module included in the mask drying apparatus of FIG. 1.

Referring to FIGS. 2 and 3, the thermoelectric module 140 may include a power supplier 1410, a first terminal 1420, a second terminal 1430, an N-type thermoelectric semiconductor element 1440, a P-type thermoelectric semiconductor element 1450, a first connecting electrode 1460, a second connecting electrode 1470, the first plate 142, and the second plate 144.

In an embodiment, when a voltage having a negative level is applied to the first terminal 1420 and a voltage having a positive level is applied to the second terminal 1430, heat may be released from the first plate 142. In addition, heat may be absorbed around the second plate 144.

In an embodiment, when a voltage having a positive level is applied to the first terminal 1420 and a voltage having a negative level is applied to the second terminal 1430, heat may be absorbed around the first plate 142. In addition, heat may be released from the second plate 144. However, a relationship among the first terminal 1420, the second terminal 1430, the first plate 142, and the second plate 144 according to embodiments of the present disclosure may not be limited thereto, and the relationship among the first terminal 1420, the second terminal 1430, the first plate 142, and the second plate 144 may vary depending on the design of the thermoelectric module 140.

The N-type thermoelectric semiconductor element 1440 may be a semiconductor element into which an N-type impurity is injected. The P-type thermoelectric semiconductor element 1450 may be a semiconductor element into which a P-type impurity is injected. The N-type thermoelectric semiconductor element 1440 and the P-type thermoelectric semiconductor element 1450 may be spaced apart from each other between the first plate 142 and the second plate 144. In addition, the N-type thermoelectric semiconductor element 1440 and the P-type thermoelectric semiconductor element 1450 may be alternately located between the first plate 142 and the second plate 144. The N-type thermoelectric semiconductor element 1440 and the P-type thermoelectric semiconductor element 1450 may be electrically connected to each other by the first connecting electrode 1460 or the second connecting electrode 1470. Specifically, the P-type thermoelectric semiconductor element 1450 and the N-type thermoelectric semiconductor element 1440 adjacent thereto may be commonly connected to any one of the first connecting electrode 1460 or the second connecting electrode 1470.

For example, referring to FIGS. 2 and 3, if the P-type thermoelectric semiconductor element 1450 located at the uppermost side is referred to as a “first thermoelectric semiconductor element” and the N-type thermoelectric semiconductor element 1440 adjacent to the first thermoelectric semiconductor element is referred to as a “second thermoelectric semiconductor element,” one end of the first thermoelectric semiconductor element facing the first plate 142 and one end of the second thermoelectric semiconductor element facing the first plate 142 may be commonly connected to one first connecting electrode 1460. In contrast, the other end of the first thermoelectric semiconductor element facing the second plate 144 may be electrically connected to the second connecting electrode 1470, and the other end of the second thermoelectric semiconductor element facing the second plate 144 may be electrically connected to another second connecting electrode 1470 adjacent to the second connecting electrode 1470 electrically connected to the other end of the first thermoelectric semiconductor element facing the second plate 144.

In an embodiment, the N-type thermoelectric semiconductor element 1440 adjacent to the P-type thermoelectric semiconductor element 1450, and the first connecting electrode 1460 or the second connecting electrode 1470 connected to the P-type thermoelectric semiconductor element 1450 and the N-type thermoelectric semiconductor element 1440 may form a pi (π) shape in a plan view. However, a planar shape formed by the N-type thermoelectric semiconductor element 1440, the P-type thermoelectric semiconductor element 1450, the first connecting electrode 1460, and the second connecting electrode 1470 according to embodiments of the present disclosure may not be limited thereto.

The N-type thermoelectric semiconductor element 1440 and the P-type thermoelectric semiconductor element 1450 may be connected in series between the first terminal 1420 of the power supplier 1410 and the second terminal 1430 of the power supplier 1410. In other words, the N-type thermoelectric semiconductor element 1440 and the P-type thermoelectric semiconductor element 1450 may be connected in series between the first terminal 1420 and the second terminal 1430 of the power supplier 1410 through the first connecting electrode 1460 and the second connecting electrode 1470.

When a first connecting electrode 1460, among a plurality of first connecting electrodes, connected to the second terminal 1430 of the power supplier 1410 is referred to as a “first lower electrode” and another first connecting electrode 1460, among the plurality of first connecting electrodes, connected to the first terminal 1420 as a first connecting electrode 1460 different from the first connecting electrode 1460 connected to the second terminal 1430 of the power supplier 1410 is referred to as a “second lower electrode,” the first lower electrode may be connected to any one of the N-type thermoelectric semiconductor element 1440 or the P-type thermoelectric semiconductor element 1450, and the second lower electrode may be connected to the other one of the P-type thermoelectric semiconductor element 1450 or the N-type thermoelectric semiconductor element 1440. For example, as illustrated in FIG. 2, the first lower electrode may be the first connecting electrode 1460 connected to the P-type thermoelectric semiconductor element 1450, and the second lower electrode may be the first connecting electrode 1460 connected to the N-type thermoelectric semiconductor element 1440.

In other words, in FIG. 2, since the first lower electrode is connected to the positive-polarity terminal (a terminal to which a positive voltage level is applied) of the power supplier 1410 and the second lower electrode is connected to the negative-polarity terminal (a terminal to which a negative voltage level is applied) of the direct-current power supply PW, a current flow 1480 as illustrated in FIG. 2 may be formed in the plurality of second connecting electrodes. Accordingly, depending on the current flow 1480, a Peltier effect in which heat generation is generated in the first plate 142 and heat absorption is generated in the second plate 144 may be implemented.

In addition, in FIG. 3, since the first lower electrode is connected to the negative-polarity terminal (a terminal to which a negative voltage level is applied) of the power supplier 1410 and the second lower electrode is connected to the positive-polarity terminal (a terminal to which a positive voltage level is applied) of the direct-current power supply PW, a current flow 1490 as illustrated in FIG. 3 may be formed in the plurality of second connecting electrodes. Accordingly, depending on the current flow 1480, a Peltier effect in which heat absorption is generated in the first plate 142 and heat generation is generated in the second plate 144 may be implemented.

FIG. 4 is an exploded perspective view illustrating the mask of FIG. 1 in a disassembled state.

Referring to FIG. 4, a frame opening 222 penetrating the mask frame 220 in a thickness direction (e.g., a third direction DR3) may be defined in the mask frame 220. A deposition opening 242 penetrating the mask sheet 240 in the thickness direction (e.g., the third direction DR3) may be defined in the mask sheet 240. A plurality of deposition openings 242 may be located on a plane perpendicular to the third direction DR3. In a plan view, a size of the frame opening 222 may be larger than a size of the deposition opening 242. The deposition openings 242 may be located to correspond to locations where a deposition material is deposited on a substrate.

The mask sheet 240 may include a deposition area DA and a peripheral area PA. The deposition openings 242 may be located in the deposition area DA. The peripheral area PA may be adjacent to the deposition area DA. The deposition openings 242 may not be located in the peripheral area PA. A plurality of deposition areas DA may be located on the mask sheet 240 on a plane perpendicular to the third direction DR3. A plurality of deposition openings may be located in one deposition area DA.

The contact area CA may be defined as an area on the mask frame 220 where the mask sheet 240 is coupled to the mask frame 220. Since a size of the mask sheet 240 is less than a size of the mask frame 220, the contact area CA may correspond to a portion of the mask frame 220.

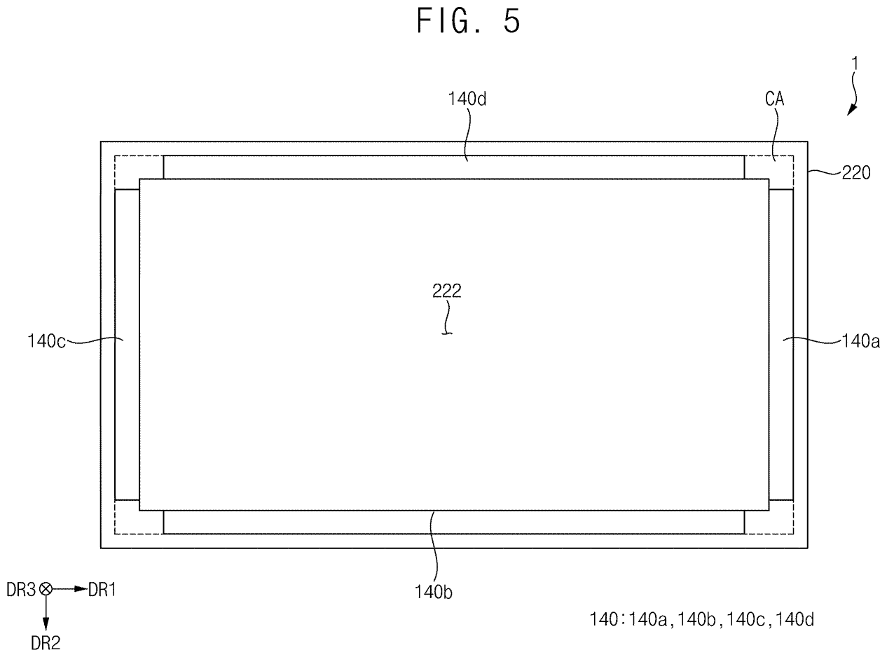

FIG. 5 is a plan view illustrating a portion of the mask drying system of FIG. 1. FIG. 6 is a bottom view illustrating a portion of the mask drying system of FIG. 1.

Referring to FIGS. 1 and 5, the thermoelectric module 140 may include a first thermoelectric module 140a, a second thermoelectric module 140b, a third thermoelectric module 140c, and a fourth thermoelectric module 140d. The first thermoelectric module 140a may extend along the second direction DR2. The second thermoelectric module 140b may extend along the first direction DR1. The third thermoelectric module 140c may extend along the second direction DR2. The fourth thermoelectric module 140d may extend along the first direction DR1 of the mask frame 220.

In an embodiment, the first thermoelectric module 140a, the second thermoelectric module 140b, the third thermoelectric module 140c, and the fourth thermoelectric module 140d may overlap the contact area CA in a plan view. For example, the first thermoelectric module 140a may be located in the first direction DR1 of the mask frame 220 and may overlap a first side extending along the second direction DR2. The second thermoelectric module 140b may be located in the second direction DR2 of the mask frame 220 and may overlap a second side extending along the first direction DR1. The third thermoelectric module 140c may be located in an opposite direction of the first direction DR1 of the mask frame 220 and may overlap a third side extending along the second direction DR2. The fourth thermoelectric module 140d may extend along the first direction DR1 of the mask frame 220 and may overlap a fourth side located in an opposite direction of the second direction DR2.

In an embodiment, the first thermoelectric module 140a, the second thermoelectric module 140b, the third thermoelectric module 140c, and the fourth thermoelectric module 140d may be spaced apart from each other at corners of the mask frame 220 in a plan view. For example, the corners may be portions of the mask frame 220 in which at least two of the first side, the second side, the third side, and the fourth side meet each other.

In an embodiment, because the thermoelectric module 140 may heat or cool a first portion in which the mask frame 220 overlaps the thermoelectric module 140 and a second portion in which the mask sheet 240 overlaps the thermoelectric module 140, a residual cleaning solution between the first portion and the second portion, and surroundings of the first portion and the second portion may be removed.

Referring to FIGS. 1 and 6, the contact area CA may include a side area SDA and a corner area CNA. For example, the corner area CNA may be defined as areas corresponding to four corners of the mask frame 220. In addition, the side area SDA may be defined as areas corresponding to four sides connecting the four corners of the mask frame 220.

The gas injection module 122 may include a first gas injection module 122a, a second gas injection module 122b, a third gas injection module 122c, and a fourth gas injection module 122d. The induction heating module 124 may include a first induction heating module 124a, a second induction heating module 124b, a third induction heating module 124c, and a fourth induction heating module 124d. The first support 164 may include a first-first support 164a, a first-second support 164b, a first-third support 164c, and a first-fourth support 164d.

In an embodiment, the first gas injection module 122a may be adjacent to a corner area CNA located in the first direction DR1 and the second direction DR2 of the mask frame 220. For example, the first gas injection module 122a may inject gas (e.g., heated air) toward the corner area CNA located in the first direction DR1 and the second direction DR2 of the mask frame 220.

In an embodiment, the second gas injection module 122b may be adjacent to a corner area CNA located in an opposite direction of the first direction DR1 and the second direction DR2 of the mask frame 220. For example, the second gas injection module 122b may inject gas (e.g., heated air) toward the corner area CNA located in the opposite direction of the first direction DR1 and the second direction DR2 of the mask frame 220.

In an embodiment, the third gas injection module 122c may be adjacent to a corner area CNA located in the opposite direction of the first direction DR1 and the opposite direction of the second direction DR2 of the mask frame 220. For example, the third gas injection module 122c may inject gas (e.g., heated air) toward the corner area CNA located in the opposite direction of the first direction DR1 and the opposite direction of the second direction DR2 of the mask frame 220.

In an embodiment, the fourth gas injection module 122d may be adjacent to a corner area CNA located in the first direction DR1 and the opposite direction of the second direction DR2 of the mask frame 220. For example, the fourth gas injection module 122d may inject gas (e.g., heated air) toward the corner area CNA located in the first direction DR1 and the opposite direction of the second direction DR2 of the mask frame 220.

In an embodiment, in a plan view, at least a portion of the first induction heating module 124a may be located in the first direction DR1 of the mask frame 220 and may overlap the side area SDA extending along the second direction DR2. In an embodiment, the first induction heating module 124a may be adjacent to the first side in a plan view. For example, the first induction heating module 124a may be located in the first direction DR1 of the mask frame 220 and may heat the first side extending along the second direction DR2.

In an embodiment, in a plan view, at least a portion of the second induction heating module 124b may be located in the second direction DR2 of the mask frame 220 and may overlap the side area SDA extending along the first direction DR1. In an embodiment, the second induction heating module 124b may be adjacent to the second side in a plan view. For example, the second induction heating module 124b may be located in the second direction DR2 of the mask frame 220 and may heat the second side extending along the first direction DR1.

In an embodiment, in a plan view, at least a portion of the third induction heating module 124c may be located in an opposite direction of the first direction DR1 of the mask frame 220 and may overlap the side area SDA extending along the second direction DR2. In an embodiment, the third induction heating module 124c may be adjacent to the third side in a plan view. For example, the third induction heating module 124c may be located in an opposite direction of the first direction DR1 of the mask frame 220 and may heat the third side extending along the second direction DR2.

In an embodiment, in a plan view, at least a portion of the fourth induction heating module 124d may be located in an opposite direction of the second direction DR2 of the mask frame 220 and may overlap the side area SDA extending along the first direction DR1. In an embodiment, the fourth induction heating module 124d may be adjacent to the fourth side in a plan view. For example, the fourth induction heating module 124d may be located in an opposite direction of the second direction DR2 of the mask frame 220 and may heat the fourth side extending along the first direction DR1.

In an embodiment, the first induction heating module 124a, the second induction heating module 124b, the third induction heating module 124c, and the fourth induction heating module 124d may partially overlap the frame opening 222. In other words, at least a portion of each of the first induction heating module 124a, the second induction heating module 124b, the third induction heating module 124c, and the fourth induction heating module 124d may be located inside the inner surface of the mask frame 220.

In an embodiment, in a plan view, the first gas injection module 122a may be located between the first induction heating module 124a and the second induction heating module 124b. In an embodiment, in a plan view, the first gas injection module 122a may overlap a corner of the mask frame 220 defined by the first side and the second side.

In an embodiment, in a plan view, the second gas injection module 122b may be located between the second induction heating module 124b and the third induction heating module 124c. In an embodiment, in a plan view, the second gas injection module 122b may overlap a corner of the mask frame 220 defined by the second side and the third side.

In an embodiment, in a plan view, the third gas injection module 122c may be located between the third induction heating module 124c and the fourth induction heating module 124d. In an embodiment, in a plan view, the third gas injection module 122c may overlap a corner of the mask frame 220 defined by the third side and the fourth side.

In an embodiment, in a plan view, the fourth gas injection module 122d may be located between the first induction heating module 124a and the fourth induction heating module 124d. In an embodiment, in a plan view, the fourth gas injection module 122d may overlap a corner of the mask frame 220 defined by the first side and the fourth side.

The first-first support 164a may support the first induction heating module 124a. For example, in a plan view, the first-first support 164a may partially overlap the first induction heating module 124a. The first-second support 164b may support the second induction heating module 124b. For example, in a plan view, the first-second support 164b may partially overlap the second induction heating module 124b. The first-third support 164c may support the third induction heating module 124c. For example, in a plan view, the first-third support 164c may partially overlap the third induction heating module 124c. The first-fourth support 164d may support the fourth induction heating module 124d. For example, in a plan view, the first-fourth support 164d may partially overlap the fourth induction heating module 124d.

As described above, in the mask drying system 1 according to the embodiments of the present disclosure, the residual cleaning solution on the sides and corners of the mask 20 may be dried (or removed) using the gas injection module 122 and the induction heating module 124. In addition, the gas injection module 122, the induction heating module 124, and the thermoelectric module 140 may apply heat to upper and lower portions of the mask 20 to easily dry (or remove) the cleaning solution. Accordingly, a mask drying system 1 capable of efficiently removing the cleaning solution may be provided.

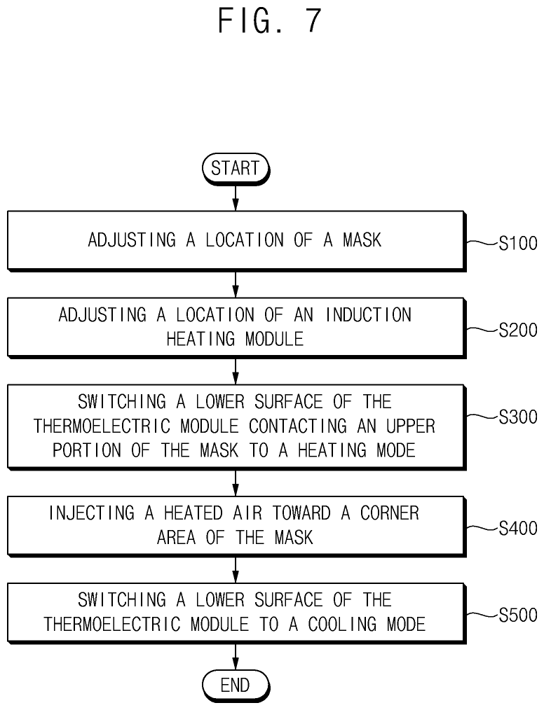

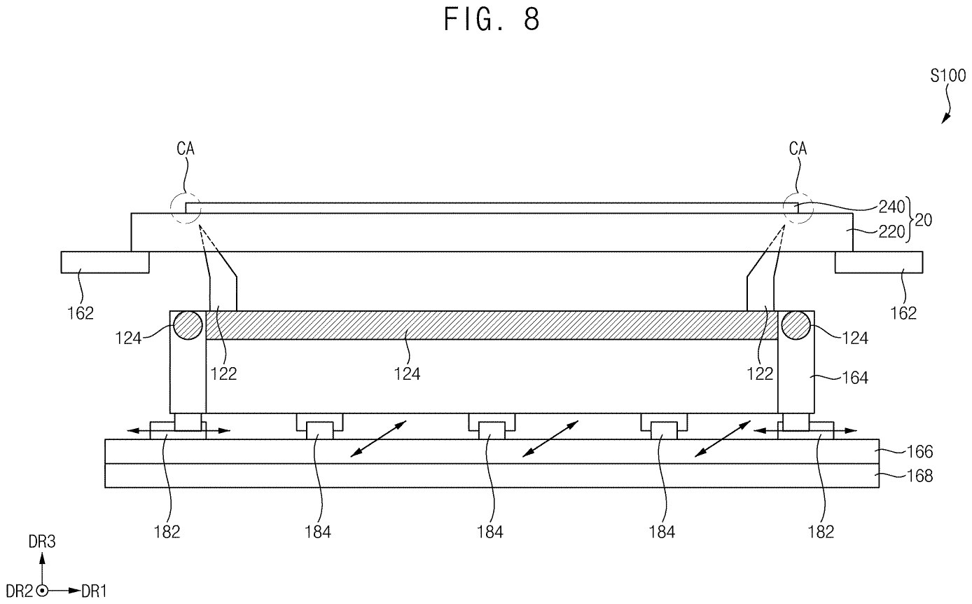

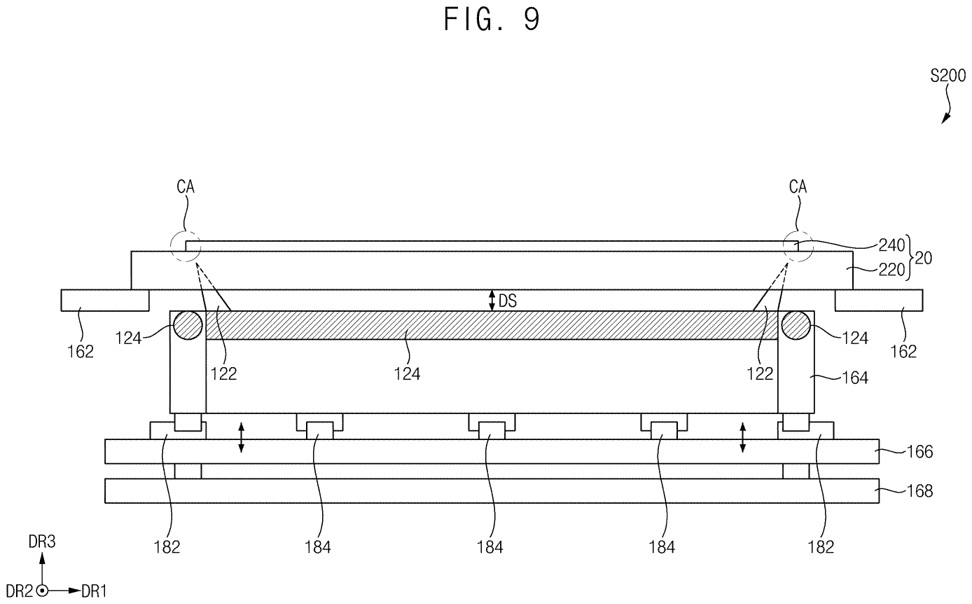

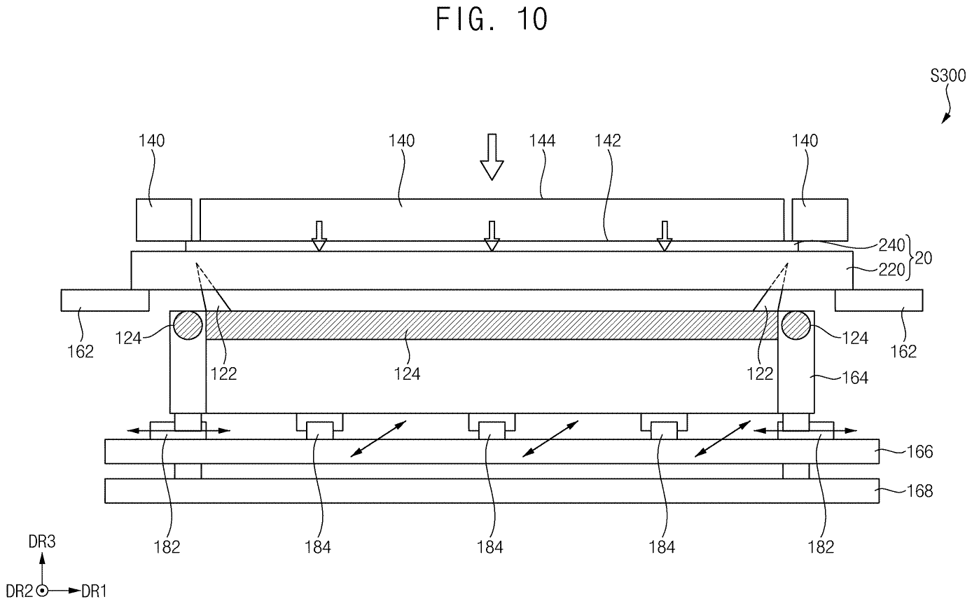

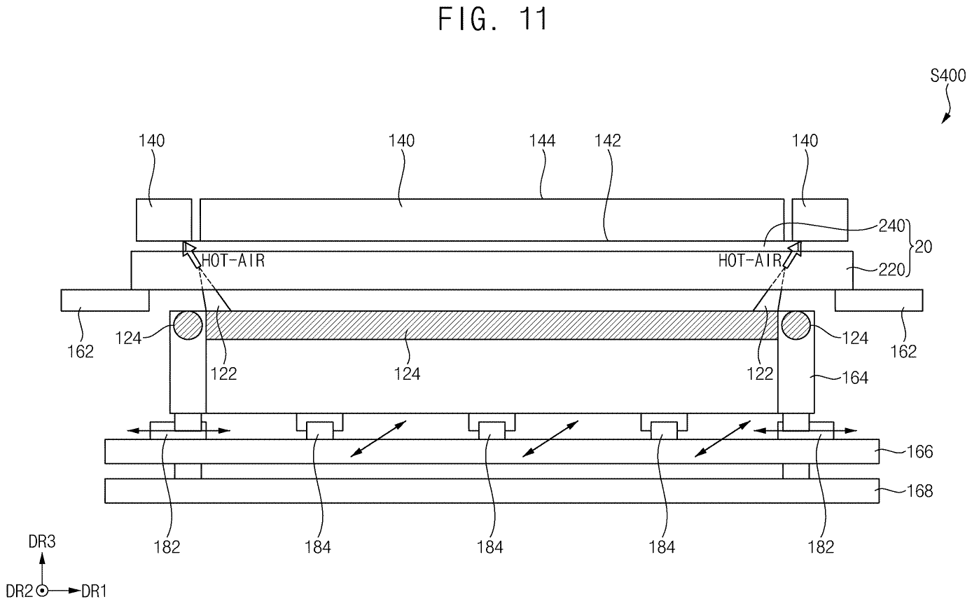

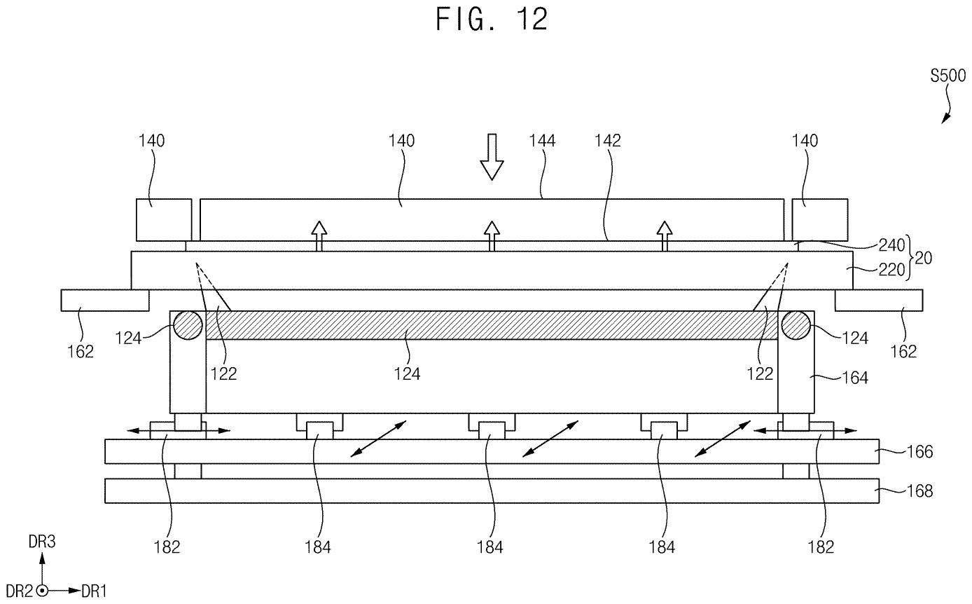

FIG. 7 is a flowchart illustrating a drying method using the mask drying system of FIG. 1. FIG. 8 is a view for explaining a adjusting a location of the mask of FIG. 7. FIG. 9 is a view for explaining a adjusting a location of an induction heating module of FIG. 7. FIG. 10 is a view for explaining a switching a lower surface of the thermoelectric module contacting an upper portion of the mask of FIG. 7 to a heating mode. FIG. 11 is a view for explaining a injecting heated air toward a corner area of the mask of FIG. 7. FIG. 12 is a view for explaining a switching the lower surface of the thermoelectric module to a cooling mode.

Hereinafter, descriptions overlapping with the contents of the mask drying system 1 described with reference to FIG. 1 may be omitted or briefly described.

Referring to FIGS. 1 and 7, a mask drying method using the mask drying system 1 may include adjusting a location of the mask 20 (S100), adjusting a location of the induction heating module 124 (S200), switching a lower surface of the thermoelectric module 140 contacting an upper portion of the mask 20 to a heating mode (S300), injecting a heated air toward the corner area (e.g., the corner area CNA of FIG. 6) of the mask 20 (S400), and switching the lower surface of the thermoelectric module 140 to a cooling mode (S500).

In an embodiment, the switching of the lower surface of the thermoelectric module 140 contacting the upper portion of the mask 20 to the heating mode (S300) may be performed after the injecting of the heated air toward the corner area of mask 20 (S400). In an embodiment, the switching of the lower surface of the thermoelectric module 140 contacting the upper portion of the mask 20 to the heating mode (S300) may be performed before the injecting of the heated air toward the corner area of mask 20 (S400).

Referring to FIG. 6 and FIGS. 8, 9, 10, 11, and 12, the mask 20 may be seated on the stage 162. For example, the mask 20 may be moved on the stage 162 in the first direction DR1 and the second direction DR2 such that locations of four sides of the mask frame 220 correspond to locations of the induction heating module 124. Specifically, the mask 20 may be moved on the stage 162 in the first direction DR1 and the second direction DR2 such that nozzles of the gas injection module 122 face four corners of the mask frame 220.

In the adjusting of the location of the induction heating module 124 (S200), the location of the induction heating module 124 may be moved using the first moving part 166, the second moving part 182, and the third moving part 184 to correspond to the location of the mask 20 seated on the stage 162.

In an embodiment, the induction heating module 124 may be moved in a direction parallel to the third direction DR3 through the first moving part 166 such that a distance DS between the induction heating module 124 and the mask frame 220 becomes an appropriate distance for performing the drying process. For example, the distance DS between the induction heating module 124 and the mask frame 220 may be about 5 mm or more to about 15 mm or less. When the distance DS between the induction heating module 124 and the mask frame 220 exceeds 15 mm, magnetic flux of the induction heating module 124 may be relatively reduced, thus increasing a temperature rise time for heating, thereby decreasing efficiency of the drying process.

In an embodiment, the induction heating module 124 may be moved in a direction parallel to the first direction DR1 through the second moving part 182. For example, the first induction heating module 124a and the third induction heating module 124c may each be moved in a direction parallel to the first direction DR1 through the second moving part 182 such that locations of the first induction heating module 124a and the third induction heating module 124c correspond to locations of two sides of the mask frame 220 extending along the second direction DR2.

In an embodiment, the induction heating module 124 may be moved in a direction parallel to the second direction DR2 through the third moving part 184. For example, the second induction heating module 124b and the fourth induction heating module 124d may each be moved in a direction parallel to the second direction DR2 through the third moving part 184 such that locations of the second induction heating module 124b and the fourth induction heating module 124d correspond to locations of two sides of the mask frame 220 extending along the first direction DR1.

Specifically, when a size of the mask frame 220 is greater than a size of a planar shape formed by the first, second, third, and fourth induction heating modules 124a, 124b, 124c, and 124d which is previously set, at least two of the first, second, third, and fourth induction heating modules 124a, 124b, 124c, and 124d may be moved away from each other through the second moving part 182 and the third moving part 184. In addition, when a size of the mask frame 220 is smaller than a size of a planar shape formed by the first, second, third, and fourth induction heating modules 124a, 124b, 124c, and 124d which is previously set, at least two of the first, second, third, and fourth induction heating modules 124a, 124b, 124c, and 124d may be moved closer to each other through the second moving part 182 and the third moving part 184.

In the switching of the lower surface of the thermoelectric module 140 contacting the upper portion of the mask 20 to the heating mode (S300), the location of the thermoelectric module 140 may be lowered so that the thermoelectric module 140 located above the mask 20 contacts the upper portion of the mask 20. After the thermoelectric module 140 contacts the upper portion of the mask 20, a lower surface (e.g., the first plate 142) of the thermoelectric module 140 may be heated as shown in FIG. 2. A temperature to which the first plate 142 is heated may be about 60 °C to about 80 °C When the heating temperature of the first plate 142 exceeds 80 °C, physical or thermal deformation may be generated in the mask 20.

In the injecting of the heated air toward the corner area of mask 20 (S400), heated air may be injected toward the corner area CNA of the mask frame 220 through the gas injection module 122. In an embodiment, the heated air may have a temperature of about 60 °C to about 80 °C However, a type of gas injected from the gas injection module 122 and a temperature of the gas according to embodiments of the present disclosure are not limited thereto, and various types of inert gas may be used or gas having various temperature distributions may be used in the drying process. Accordingly, since the drying process is performed on the corner area CNA of the mask 20 that is not directly heated by the induction heating module 124 through the gas injection module 122, efficiency of the drying process of the mask 20 may be further improved.

In an embodiment, heat may be applied to the side area SDA of the mask frame 220 using the induction heating module 124. A temperature of the induction heating module 124 may be about 60 °C to about 80 °C. The process of applying heat using the induction heating module 124 may be performed simultaneously with, before, or after the process of applying heat using the thermoelectric module 140 or the process of injecting heated air using the gas injection module 122.

In the switching of the lower surface of the thermoelectric module 140 to the cooling mode (S500), the lower surface (e.g., the first plate 142) of the thermoelectric module 140 may be switched from the heating mode to the cooling mode as shown in FIG. 3. A temperature of the first plate 142 may be cooled to about 15 °C or more. When a cooling temperature of the first plate 142 is less than about 15 °C, condensation may be generated inside the mask 20, causing a defect in the mask 20.

As described above, in the drying method using the mask drying system 1 according to embodiments of the present disclosure, heating and cooling of the drying process may be performed through switching of the thermoelectric module 140 located above the mask 20. Accordingly, efficiency of the drying process of the mask may be improved, and time and cost may be reduced.

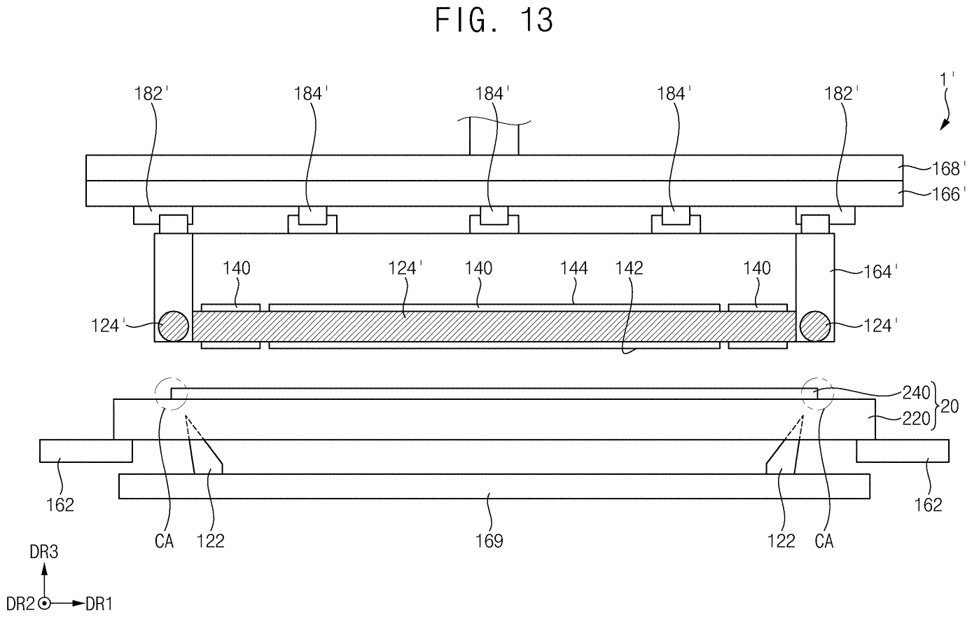

FIG. 13 is a side view illustrating a mask drying system according to another embodiment of the present disclosure.

Referring to FIG. 13, a mask drying system 1′ described with reference to FIG. 13 may be substantially the same as or similar to the mask drying system 1 described with reference to FIG. 1, except positions of an induction heating module 124′, a first support 164′, a first moving part 166′, a second support 168′, a second moving part 182′, and a third moving part 184′. Hereinafter, redundant descriptions with the contents described with reference to FIG. 1 may be omitted or briefly described.

Referring to FIG. 13, the induction heating module 124′, the first support 164′, the first moving part 166′, the second support 168′, the second moving part 182′, and the third moving part 184′ may be located above the mask 20. Since the induction heating module 124′ of the mask drying system 1′ is located above the mask 20, the mask drying system 1′ of FIG. 13 may have greater drying power for the upper portion of the mask 20 than the mask drying system 1 of FIG. 1 in which the induction heating module 124 is located under the mask 20.

In an embodiment, in a plan view, the induction heating module 124′ may be located outside the thermoelectric module 140 in a plan view. For example, the induction heating module 124′ may surround the thermoelectric module 140 in a plan view. However, the positions of the induction heating module 124′ and the thermoelectric module 140 according to embodiments of the present disclosure are not necessarily limited thereto, and the induction heating module 124′ may be located inside the thermoelectric module 140 in a plan view, or the induction heating module 124′ and the thermoelectric module 140 may be located to overlap each other in a plan view. In a case in which the induction heating module 124′ and the thermoelectric module 140 overlap each other in a plan view, the induction heating module 124′ may be located above or below the thermoelectric module 140.

As the induction heating module 124′ is located above the mask 20, the first moving part 166′, the first support 168′, the second moving part 182′, and the third moving part 184′, which support the induction heating module 124′ or adjust the location of the induction heating module 124′, may be located above the mask 20 and the thermoelectric module 140. In addition, the first support 168′ may have its location fixed by a fixing means coupled to an upper side surface of a process chamber. However, a method of fixing positions of the induction heating module 124′, the first moving part 166′, the first support 168′, the second moving part 182′, and the third moving part 184′ according to embodiments of the present disclosure may not be necessarily limited thereto.

As described above, in the mask drying system 1′ according to embodiments of the present disclosure, cleaning liquid remaining on sides and corners of the mask 20 may be dried (or removed) using the gas injection module 122 and the induction heating module 124′. In addition, the cleaning liquid may be easily dried (or removed) by applying heat to the upper portion and the lower portion of the mask 20 through the gas injection module 122, the induction heating module 124′, and the thermoelectric module 140. Accordingly, a mask drying system 1′ capable of efficiently removing the cleaning liquid may be provided. In addition, since the induction heating module 124′ of the mask drying system 1′ is located above the mask 20, drying power for the upper portion of the mask 20 may be further improved.

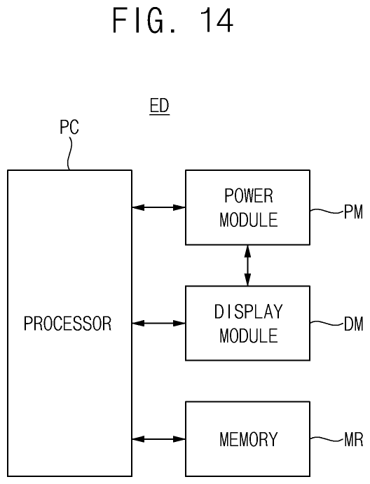

FIG. 14 is a block diagram illustrating an electronic device manufactured using the mask of FIG. 1.

The mask 20 of FIG. 1 according to embodiments may be used for manufacturing various electronic devices. An electronic device according to an embodiment may include the above-described display device, and may further include a module or device having another additional function in addition to the display device.

Referring to FIG. 14, an electronic device ED according to an embodiment may include a display module DM, a processor PC, a memory MR, and a power module PM.

The processor PC may include at least one of a central processing unit (CPU: central processing unit), an application processor (AP: application processor), a graphic processing unit (GPU: graphic processing unit), a communication processor (CP: communication processor), an image signal processor (ISP: image signal processor), and a controller.

The memory MR may store data information necessary for the operation of the processor PC or the display module DM. When the processor PC executes an application stored in the memory MR, an image data signal and/or an input control signal may be delivered to the display module DM, and the display module DM may process the provided signal to output image information through a display screen.

The power module PM may include a power supply module such as a power adapter or a battery device, and a power conversion module for converting power supplied by the power supply module to generate power necessary for the operation of the electronic device ED.

At least one of the components of the above-described electronic device ED may be included in the display device according to the embodiments described above. In addition, among individual modules functionally included in one module, some may be included in the display device and others may be provided separately from the display device. For example, the display device may include the display module DM, and the processor PC, the memory MR, and the power module PM may be provided in a form of another device in the electronic device ED other than the display device.

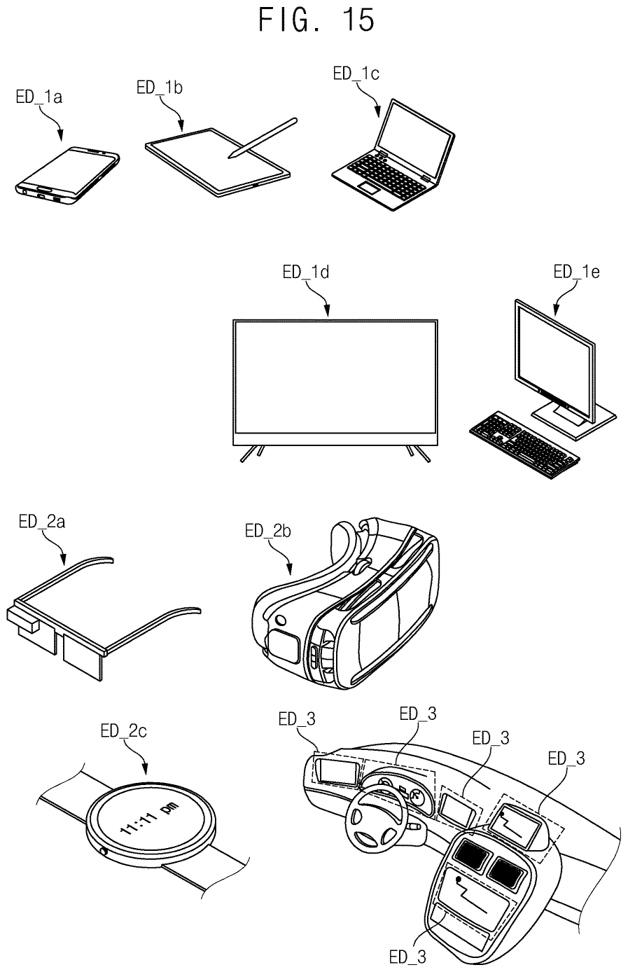

FIG. 15 is schematic views illustrating various embodiments of the electronic device of FIG. 14.

Referring to FIG. 15, various electronic devices to which the display device according to embodiments is applied may include not only image display electronic devices such as a smartphone ED_1a, a tablet PC ED_1b, a laptop ED_1c, a TV ED_1d, and a desktop monitor ED_1e, but also wearable electronic devices including a display module such as smart glasses ED_2a, a head-mounted display ED_2b, and a smart watch ED_2c, and vehicle electronic devices ED_3 including a display module such as a CID (Center Information Display) located on an instrument panel, a center fascia, and a dashboard of a vehicle, and a room mirror display.

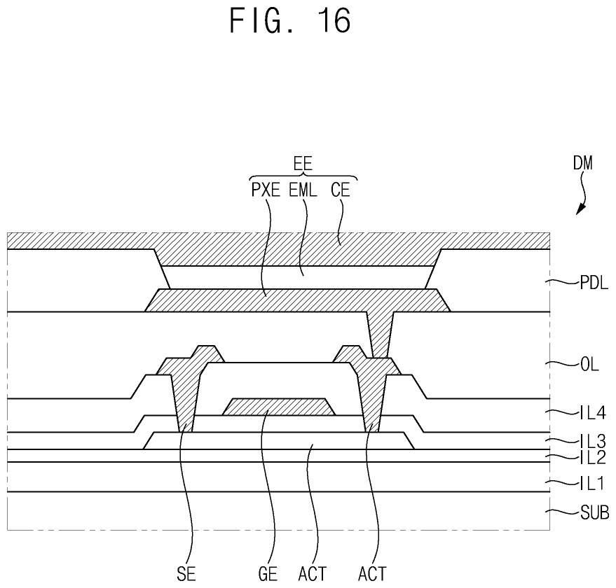

FIG. 16 is a cross-sectional view illustrating a portion of a display module of FIG. 14.

Referring to FIG. 16, the display module DM according to an embodiment of the present disclosure may include a base substrate SUB, a first insulating layer IL1, a second insulating layer IL2, an active layer ACT, a third insulating layer IL3, a gate electrode GE, a fourth insulating layer IL4, a source electrode SE, a drain electrode DE, an organic layer OL, a light-emitting element EE, and a pixel defining layer PDL. The light-emitting element EE may include a pixel electrode PXE, a light-emitting layer EML, and a common electrode CE.

The display module DM may include a component (e.g., a pixel) for emitting light. The pixel may include a pixel circuit portion and the light-emitting element EE. The pixel circuit portion may include at least one transistor. The transistor may include the active layer ACT, the gate electrode GE, the source electrode SE, and the drain electrode DE.

The base substrate SUB may form a base of the display module DM. In an embodiment, the base substrate SUB may be a glass substrate. In an embodiment, the base substrate SUB may be a silicon wafer. In an embodiment, the base substrate SUB may include at least one barrier layer including an organic material. However, a type of the base substrate SUB according to embodiments of the present disclosure may not be limited thereto.

The first insulating layer IL1 may be located on the base substrate SUB. In an embodiment, the first insulating layer IL1 may include an inorganic insulating material. The first insulating layer IL1 may prevent impurities from diffusing from the base substrate SUB to the active layer ACT. The second insulating layer IL2 may be located on the first insulating layer IL1. In an embodiment, the second insulating layer IL2 may include an inorganic insulating material.

The active layer ACT may be located on the second insulating layer IL2. In an embodiment, the active layer ACT may include an oxide semiconductor or polycrystalline silicon. However, a type of a material included in the active layer ACT according to embodiments of the present disclosure may not be limited thereto.

The third insulating layer IL3 may be located on the active layer ACT. In an embodiment, the third insulating layer IL3 may cover the active layer ACT. In an embodiment, the third insulating layer IL3 may include an inorganic insulating material.

The gate electrode GE may be located on the third insulating layer IL3. In an embodiment, the gate electrode GE may include a conductive material. The gate electrode GE may overlap the active layer ACT in a plan view. For example, a portion of the active layer ACT overlapping the gate electrode GE may be a channel area of the active layer ACT.

The fourth insulating layer IL4 may be located on the third insulating layer IL3. In an embodiment, the fourth insulating layer IL4 may cover the gate electrode GE. In an embodiment, the fourth insulating layer IL4 may include an inorganic insulating material.

The source electrode SE and the drain electrode DE may be located on the fourth insulating layer IL4. In an embodiment, the source electrode SE and the drain electrode DE may include a conductive material. The source electrode SE and the drain electrode DE may contact the active layer ACT. For example, the source electrode SE and the drain electrode DE may contact the active layer ACT through a hole penetrating the third insulating layer IL3 and the fourth insulating layer IL4 in a thickness direction (e.g., a third direction DR3).

The organic layer OL may be located on the fourth insulating layer IL4. The organic layer OL may provide a substantially flat upper surface. The organic layer OL may include an organic insulating material. The organic layer OL may have a hole defined therein to expose the drain electrode DE.

The pixel electrode PXE may be located on the organic layer OL. In an embodiment, the pixel electrode PXE may include a conductive material. The pixel electrode PXE may contact the drain electrode DE through the hole penetrating the organic layer OL in the thickness direction (e.g., the third direction DR3). However, the pixel electrode PXE according to embodiments of the present disclosure may not be limited thereto, and the pixel electrode PXE may contact the source electrode SE.

The pixel defining layer PDL may be located on the organic layer OL. In an embodiment, the pixel defining layer PDL may include an organic insulating material. The pixel defining layer PDL may partially cover the pixel electrode PXE. For example, the pixel defining layer PDL may expose a center of the pixel electrode PXE and may cover an edge of the pixel electrode PXE.

The light-emitting layer EML may be located on the pixel electrode PXE. In an embodiment, the light-emitting layer EML may include a light-emitting material such as an organic light-emitting material or quantum dots. The common electrode CE may be located on the light-emitting layer EML. In an embodiment, the common electrode CE may include a conductive material.

However, components included in the display module DM according to embodiments of the present disclosure may not be limited thereto, and the display module DM may further include other components (e.g., a thin film encapsulation layer, a color filter layer, and a window).

The method and the system according to the embodiments may be applied to a display device included in a computer, a notebook, a mobile phone, a smartphone, a smart pad, a PMP, a PDA, an MP3 player, or the like.

Although the methods and the systems according to the embodiments have been described with reference to the drawings, the illustrated embodiments are examples, and may be modified and changed by a person having ordinary knowledge in the relevant technical field without departing from the technical spirit described in the following claims.

What is claimed is:

1. A mask drying system comprising:
an induction heating module configured to heat a mask which includes a mask frame and a mask sheet, and disposed on the induction heating module;
a thermoelectric module disposed on an upper portion of the mask; and
a moving part disposed on the induction heating module and configured to move the induction heating module on a plane parallel to a surface of the mask frame.

2. The mask drying system of claim 1, wherein the thermoelectric module includes:
a first thermoelectric module overlapping a first side of the mask frame in a plan view, wherein the first side is located from the mask frame in a first direction and extends along a second direction crossing the first direction;
a second thermoelectric module overlapping a second side of the mask frame, wherein the second side is located from the mask frame in the second direction and extends along the first direction;
a third thermoelectric module overlapping a third side of the mask frame, wherein the third side is located from a direction opposite to the first direction, and extends along the second direction; and
a fourth thermoelectric module overlapping a fourth side of the mask frame, wherein the fourth side is located from a direction opposite to the second direction and extends along the first direction.

3. The mask drying system of claim 2, wherein the induction heating module includes:
a first induction heating module adjacent to the first side and configured to heat the first side;
a second induction heating module adjacent to the second side and configured to heat the second side;
a third induction heating module adjacent to the third side and configured to heat the third side; and
a fourth induction heating module adjacent to the fourth side and configured to heat the fourth side.

4. The mask drying system of claim 3, further comprising:
a gas injecting module under the mask and configured to inject heated air toward a corner of the mask frame, wherein the corner is a region in which at least two of the first side, the second side, the third side, and the fourth side meet each other.

5. The mask drying system of claim 4, wherein the gas injecting module includes:
a first gas spraying module overlapping a corner of the mask frame in which the first side and the second side meet each other in a plan view;
a second gas injecting module overlapping a corner of the mask frame in which the second side and the third side meet each other in a plan view;
a third gas injecting module overlapping a corner of the mask frame in which the third side and the fourth side meet each other in a plan view; and
a fourth gas injecting module overlapping a corner of the mask frame in which the first side and the fourth side meet each other in a plan view.

6. The mask drying system of claim 5, wherein the first gas injecting module is located between the first induction heating module and the second induction heating module in a plan view, the second gas injecting module is located between the second induction heating module and the third induction heating module in a plan view, the third gas injecting module is located between the third induction heating module and the fourth induction heating module in a plan view, and the fourth gas injecting module is located between the first induction heating module and the fourth induction heating module in a plan view.

7. The mask drying system of claim 3, wherein the first induction heating module, the second induction heating module, the third induction heating module, and the fourth induction heating module are spaced apart from each other at the corner of the mask frame in a plan view.

8. The mask drying system of claim 3, wherein the first induction heating module, the second induction heating module, the third induction heating module, and the fourth induction heating module are located below the mask.

9. The mask drying system of claim 8, wherein the first induction heating module, the second induction heating module, the third induction heating module, and the fourth induction heating module partially overlap a frame opening of the mask frame.

10. The mask drying system of claim 3, wherein the first induction heating module, the second induction heating module, the third induction heating module, and the fourth induction heating module are located above the mask.

11. The mask drying system of claim 10, wherein the first induction heating module, the second induction heating module, the third induction heating module, and the fourth induction heating module surround the first thermoelectric module, the second thermoelectric module, the third thermoelectric module, and the fourth thermoelectric module in a plan view.

12. The mask drying system of claim 2, wherein the moving part includes:
a first moving part coupled to the first induction heating module and the third induction heating module and configured to move the first induction heating module and the third induction heating module in a direction parallel to the first direction; and
a second moving part coupled to the second induction heating module and the fourth induction heating module and configured to move the second induction heating module and the fourth induction heating module in a direction parallel to the second direction.

13. A mask drying method comprising:
adjusting a location of an induction heating module corresponding to a location of a mask;
heating the mask by switching a surface of a thermoelectric module facing the mask to a heating mode;
injecting a heated air toward a corner in which at least two of sides of the mask meet each other; and
switching the surface of the thermoelectric module to a cooling mode.

14. The mask drying method of claim 13, wherein the adjusting of the location of the induction heating module corresponding to the location of the mask includes:
moving the induction heating module so that the induction heating module overlaps the sides of the mask in a plan view; and
adjusting a distance between the mask and the induction heating module.

15. The mask drying method of claim 14, wherein the distance between the mask and the induction heating module is from about 5 mm to about 15 mm.

16. The mask drying method of claim 13, wherein, in the heating of the mask by switching the surface of the thermoelectric module facing the mask to the heating mode, a temperature of the surface of the thermoelectric module is from about 60 °C to about 80 °C.

17. The mask drying method of claim 13, wherein, the injecting of the heated air toward the corner, a temperature of the heated air is from about 60 °C to about 80 °C.

18. The mask drying method of claim 13, further comprising:
heating the sides of the mask by using the induction heating module.

19. The mask drying method of claim 18, wherein, in the heating of the sides of the mask by using the induction heating module, a temperature of the induction heating module is from about 60 °C to about 80 °C.

20. The mask drying method of claim 13, wherein, in the switching of the surface of the thermoelectric module to the cooling mode, a temperature of the surface of the thermoelectric module is about 15 °C or more.
